(19) United States
(12) Patent Application Publication
(10) Pub. No.: US 2026/0001776 A1
(43) Pub. Date: Jan. 1, 2026

(54) TUNGSTEN PRECURSORS FOR DEPOSITION PROCESSES

(71) Applicant: ENTEGRIS, INC., Billerica, MA (US)

(72) Inventors: Robert Halbach, Burnet, TX (US); Pei Zhao, Leander, TX (US); Cameron Barbee, Marble Falls, TX (US)

(21) Appl. No.: 19/251,769

(22) Filed: Jun. 26, 2025

Related U.S. Application Data
(60) Provisional application No. 63/666,003, filed on Jun. 28, 2024.

(51) Int. Cl. C01G 41/04; C23C 16/08

(52) U.S. Cl. CPC C01G 41/04; C23C 16/08; C01P 2002/77; C01P 2006/80

(57) ABSTRACT

Compositions are provided. A composition comprises a tungsten pentachloride compound. The tungsten pentachloride compound has an orthorhombic crystal structure as determined using Single-Crystal X-ray Diffraction. A method comprises obtaining a precursor, vaporizing the precursor to obtain a vaporized precursor, and exposing, under vapor deposition conditions, a substrate to the vaporized precursor. The precursor comprises a tungsten pentachloride compound having an orthorhombic crystal structure as determined by Single-Crystal X-Ray Diffraction. Related precursors and related methods are also provided, among other things.

### CROSS-REFERENCE TO RELATED APPLICATIONS

This application claims the benefit under 35 USC 119 of U.S. Provisional Patent Application No. 63/666,003, filed Jun. 28, 2024, the disclosure of which is hereby incorporated herein by reference in its entirety.

### FIELD

The present disclosure relates to tungsten precursors for deposition processes, and related compositions, systems, and methods.

### BACKGROUND

Films can be used in applications during the manufacture of microelectronic devices. Some of the films can be made using chemical vapor deposition (CVD) or atomic layer deposition (ALD).

### SUMMARY

Some embodiments relate to a composition. The composition comprises a tungsten pentachloride compound. In some embodiments, the tungsten pentachloride compound has an orthorhombic crystal structure as determined using Single-Crystal X-ray Diffraction.

Some embodiments relate to a precursor. The precursor comprises a tungsten pentachloride compound. The tungsten pentachloride compound may have an orthorhombic crystal structure.

Some embodiments relate to a method. In some embodiments, the method comprises obtaining a precursor. In some embodiments, the precursor comprises a tungsten pentachloride compound. In some embodiments, the tungsten pentachloride compound has an orthorhombic crystal structure as determined by Single-Crystal X-Ray Diffraction. In some embodiments, the method comprises vaporizing the precursor to obtain a vaporized precursor. In some embodiments, the method comprises exposing, under vapor deposition conditions, a substrate to the vaporized precursor.

### BRIEF DESCRIPTION OF THE DRAWINGS

FIG. 1 is a schematic diagram of a flowchart of a method, according to some embodiments.

FIG. 2 is a perspective view of an orthorhombic crystal structure as determined using Single-Crystal X-ray Diffraction, according to some embodiments.

FIG. 3 is an oblique view of an orthorhombic crystal structure as determined using Single-Crystal X-ray Diffraction, according to some embodiments.

FIG. 4 is an isometric view of an orthorhombic crystal structure as determined using Single-Crystal X-ray Diffraction, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure, which are intended to be illustrative, and not restrictive.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

Some embodiments relate to compositions useful in chemical vapor depositions (CVD), among other applications, and related precursors. The compositions disclosed herein comprise tungsten pentachloride compounds. The tungsten pentachloride compounds may be used to form tungsten pentachloride-containing films useful in the fabrication of microelectronic devices, including semiconductor devices. The compositions may be used as deposition precursors for generating tungsten pentachloride-containing films.

Some embodiments relate to a composition. The composition comprises a tungsten pentachloride compound. In some embodiments, the tungsten pentachloride compound has an orthorhombic crystal structure. In some embodiments, the orthorhombic crystal structure may be determined using Single-Crystal X-ray Diffraction.

The orthorhombic structure may be characterized by the geometry of the unit cell, specifically six lattice parameters taken as the lengths of the cell edges (a, b, c) and the angles between them (alpha, beta, gamma). The unit cell parameters are calculated from experimental data collected during Single-Crystal X-ray Diffraction. The lattice cell parameters distinguish the orthorhombic structure.

In some embodiments, when analyzed by Single-Crystal X-ray Diffraction to determine unit cell dimensions of the tungsten pentachloride compound, lengths of edges a, b, and c of the tungsten pentachloride compound are sufficient for angles α, β, and γ to be 90°.

In some embodiments, the composition may have unit cell dimensions of:

$$a ( A ) = 11.5854 ( 5 )$$

$$b ( A ) = 17.7108 ( 8 )$$

$$c ( A ) = 6.0637 ( 3 )$$

$$α ( ° ) = 90$$

$$β ( ° ) = 90$$

$$γ ( ° ) = 90$$

$$cell volume ( {A}^{3} ) = 1244.19 ( 10 )$$

$$Z - 4.$$

In some embodiments, the unit cell dimensions may be determined using Single-Crystal X-ray Diffraction.

In some embodiments, the tungsten pentachloride compound has a space group of Pnma as determined using Single-Crystal X-ray Diffraction. The Pnma space group is centrosymmetric with three mutually perpendicular 21 screw axes and three mutually perpendicular planes (class mmm).

In some embodiments, the tungsten pentachloride compound has a point group of mmm as determined using Single-Crystal X-ray Diffraction. The mmm point group contains three mutually-orthogonal mirror planes and three mutually-orthogonal twofold rotation axes.

In some embodiments, when measured at a temperature of 100 K to 300 K, the tungsten pentachloride compound has a density of 3.8 g/cm³ to 4 g/cm³.

In some embodiments, the tungsten pentachloride compound may have a purity of at least 95%. For example, in some embodiments, the tungsten pentachloride compound has a purity of 95% to 99.9999%, or any range or subrange between 95% and 99.9999%. In some embodiments, the tungsten pentachloride compound has a purity of 95% to 99.9999%, 96% to 99.9999%, 97% to 99.9999%, 98% to 99.9999%, 99% to 99.9999%, 99.9% to 99.9999%, 99.99% to 99.9999%, 99.999% to 99.9999%, 95% to 99.999%, 95% to 99.999%, 95% to 99.99%, 95% to 99.9%, 95% to 99%, 95% to 98%, 95% to 97%, 95% to 96%.

Some embodiments relate to a composition. The composition comprises a tungsten pentachloride compound. In some embodiments, the tungsten pentachloride compound does not have a monoclinic crystal structure as determined using Single-Crystal X-ray Diffraction. In some embodiment, the tungsten pentachloride compound has a non-monoclinic crystal structure. The non-monoclinic crystal structure may comprise a triclinic crystal structure, an orthorhombic crystal structure, a tetragonal crystal structure, a hexagonal crystal structure, and a cubic crystal structure.

In some embodiments, the composition may have unit cell dimensions of:

$$a ( A ) = 11.5854 ( 5 )$$

$$b ( A ) = 17.7108 ( 8 )$$

$$c ( A ) = 6.0637 ( 3 )$$

$$α ( ° ) = 90$$

$$β ( ° ) = 90$$

$$γ ( ° ) = 90$$

$$cell volume ( {A}^{3} ) = 1244.19 ( 10 )$$

$$Z - 4.$$

As disclosed herein, the unit cell dimensions may be determined using Single-Crystal X-ray Diffraction. The tungsten pentachloride compound may have a space group of Pnma as determined using Single-Crystal X-ray Diffraction.

In some embodiments, the tungsten pentachloride compound may have point group of mmm as determined using Single-Crystal X-ray Diffraction.

In some embodiments, the tungsten pentachloride compound may have a purity level of at least 99%, as disclosed herein.

In some embodiments, when measured at a temperature of 100 K to 300 K, the tungsten pentachloride compound has a density of 3.8 g/cm³ to 4 g/cm³.

Some embodiments relate to a precursor. The precursor comprises a tungsten pentachloride compound. The tungsten pentachloride compound may have an orthorhombic crystal structure as described herein.

The precursor may have a unit cell dimension of:

$$a ( A ) = 11.5854 ( 5 )$$

$$b ( A ) = 17.7108 ( 8 )$$

$$c ( A ) = 6.0637 ( 3 )$$

$$α ( ° ) = 90$$

$$β ( ° ) = 90$$

$$γ ( ° ) = 90$$

$$cell volume ( {A}^{3} ) = 1244.19 ( 10 )$$

$$Z - 4.$$

As disclosed herein, the unit cell dimensions may be determined using Single-Crystal X-ray Diffraction.

In some embodiments, the tungsten pentachloride compound point group may be mmm as determined using single-crystal X-ray diffraction described herein. The tungsten pentachloride compound may have space group of Pnma as determined using Single-Crystal X-ray Diffraction described herein.

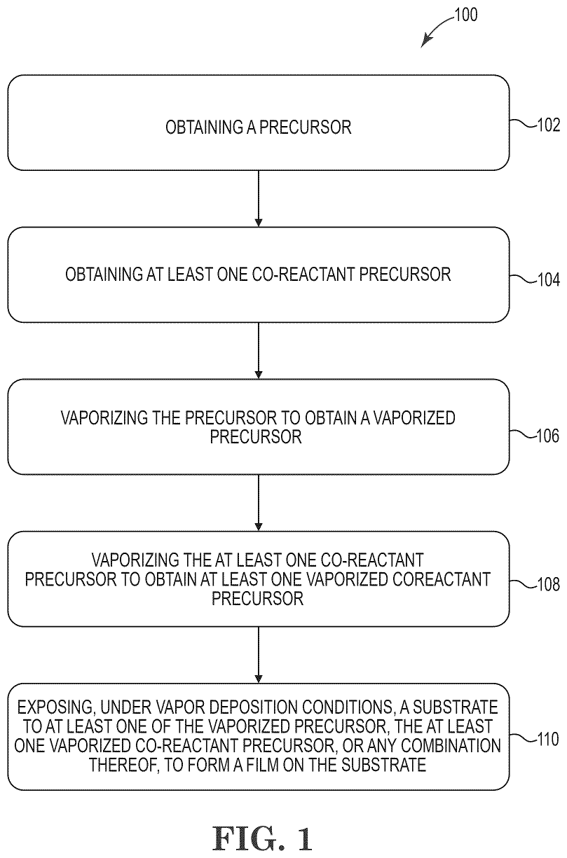

FIG. 1 is a flowchart of a method 100 of vapor deposition, according to some embodiments. As shown in FIG. 1, the method 100 of vapor deposition may comprise one or more of the following steps: obtaining 102 a precursor, obtaining 104 at least one co-reactant precursor, vaporizing 106 the precursor to obtain a vaporized precursor, vaporizing 108 the at least one co-reactant precursor to obtain at least one vaporized co-reactant precursor, exposing 110, under vapor deposition conditions, a substrate to at least one of the vaporized precursor, the at least one vaporized co-reactant precursor, or any combination thereof, to form a film on the substrate.

At step 102, in some embodiments, the method comprises obtaining a precursor. The precursor may comprise any one or more of the vapor deposition precursors disclosed herein. For example, in some embodiments, the precursor comprises a tungsten pentachloride compound. In some embodiments, the tungsten pentachloride compound has an orthorhombic crystal structure as determined using Single-Crystal X-ray Diffraction. In some embodiments, the tungsten pentachloride compound has a non-monoclinic crystal structure as determined using Single-Crystal X-ray Diffraction. It will be appreciated that any one or more of the compositions and compounds, including tungsten pentachloride compounds, among others, may be employed without departing from the scope of this disclosure. In some embodiments, the obtaining comprises obtaining a vessel comprising the precursor. In some embodiments, the obtaining comprises obtaining a container comprising the precursor. In some embodiments, the precursor may be obtained in a container or other vessel in which the precursor is to be vaporized.

At step 104, in some embodiments, the method comprises obtaining at least one co-reactant precursor. In some embodiments, the at least one co-reactant precursor comprises at least one of an oxidizing gas, a reducing gas, a hydrocarbon, or any combination thereof. The at least one co-reactant precursor may be selected to obtain a desired film. In some embodiments, the at least one co-reactant precursor comprises at least one of N₂, H₂, NH₃, N₂H₄, CH₃HNNH₂, CH₃HNNHCH₃, NCH₃H₂, NCH₃CH₂H₂, N(CH₃)₂H, N(CH₃CH₂)₂H, N(CH₃)₃, N(CH₃CH₂)₃, Si(CH₃)₂NH, pyrazoline, pyridine, ethylene diamine, a radical thereof, or any combination thereof. In some embodiments, the at least one co-reactant precursor comprises at least one of H₂, O₂, O₃, H₂O, H₂O₂, NO, N₂O, NO₂, CO, CO₂, a carboxylic acid, an alcohol, a diol, a radical thereof, or any combination thereof. In some embodiments, the at least one co-reactant precursor comprises at least one of methane, ethane, ethylene, acetylene, or any combination thereof. The obtaining may comprise obtaining a container or other vessel comprising the at least one co-reactant precursor. In some embodiments, the at least one co-reactant precursor may be obtained in a container or other vessel in which the at least one co-reactant precursor is to be vaporized. In some embodiments, the method further comprises an inert gas, such as, for example, at least one of argon, helium, nitrogen, or any combination thereof.

At step 106, in some embodiments, the method comprises vaporizing the precursor to obtain a vaporized precursor. The vaporizing may comprise heating the precursor sufficient to obtain the vaporized precursor. In some embodiments, the vaporizing comprises heating a container comprising the precursor. In some embodiments, the vaporizing comprises heating the precursor in a deposition chamber in which the vapor deposition process is performed. In some embodiments, the vaporizing comprises heating a conduit for delivering the precursor, the vaporized precursor, or any combination thereof to, for example, a deposition chamber. In some embodiments, the vaporizing comprises operating a vapor delivery system comprising the precursor. In some embodiments, the vaporizing comprises heating to a temperature sufficient to vaporize the precursor to obtain the vaporized precursor. In some embodiments, the vaporizing comprises heating to a temperature below a decomposition temperature of at least one of the precursor, the vaporized precursor, or any combination thereof. In some embodiments, the precursor may be present in a gas phase or other vaporizable phase, in which case the step 106 is optional and not required. For example, in some embodiments, the precursor comprises the vaporized precursor.

At step 108, in some embodiments, the method comprises vaporizing the at least one co-reactant precursor to obtain the at least one vaporized co-reactant precursor. In some embodiments, the vaporizing comprises heating the at least one co-reactant precursor sufficient to obtain the at least one vaporized co-reactant precursor. In some embodiments, the vaporizing comprises heating a container comprising the at least one co-reactant precursor. In some embodiments, the vaporizing comprises heating the at least one co-reactant precursor in a deposition chamber in which the vapor deposition process is performed. In some embodiments, the vaporizing comprises heating a conduit for delivering the at least one co-reactant precursor, the at least one vaporized co-reactant precursor, or any combination thereof to, for example, a deposition chamber. In some embodiments, the vaporizing comprises operating a vapor delivery system comprising the at least one co-reactant precursor. In some embodiments, the vaporizing comprises heating to a temperature sufficient to vaporize the at least one co-reactant precursor to obtain the at least one vaporized co-reactant precursor. In some embodiments, the vaporizing comprises heating to a temperature below a decomposition temperature of at least one of the at least one co-reactant precursor, the at least one vaporized co-reactant precursor, or any combination thereof. In some embodiments, the at least one co-reactant precursor may be present in a gas phase or other vaporizable phase, in which case the step 108 is optional and not required. For example, in some embodiments, the at least one co-reactant precursor comprises the at least one vaporized co-reactant precursor.

At step 110, in some embodiments, the method comprises exposing, under vapor deposition conditions, a substrate to at least one of the vaporized precursor, the at least one vaporized co-reactant precursor, or any combination thereof, to form a film on the substrate. The exposing may be performed in any system, apparatus, device, assembly, chamber thereof, or component thereof suitable for vapor deposition processes, including, for example and without limitation, a deposition chamber, among others. In some embodiments, the exposing comprises contacting the substrate with at least one of the vaporized precursor, the at least one vaporized co-reactant precursor, or any combination thereof. The vaporized precursor and the at least one co-reactant precursor may be contacted with the substrate at the same time or at different times. For example, each of the vaporized precursor, the at least one vaporized co-reactant precursor, and the substrate may be present in the deposition chamber at the same time. That is, in some embodiments, the contacting may comprise contemporaneous contacting or simultaneous contacting of the vaporized precursor and the at least one vaporized co-reactant precursor with the substrate. Alternatively, each of the vaporized precursor and the at least one vaporized co-reactant precursor may be present in the deposition chamber at different times. That is, in some embodiments, the contacting may comprise alternate and/or sequential contacting, in one or more cycles, of the vaporized precursor with the substrate and subsequently contacting the at least one vaporized co-reactant precursor with the substrate.

The vapor deposition conditions may comprise conditions for vapor deposition processes. Examples of vapor deposition conditions include, without limitation, vapor deposition conditions for vapor deposition processes including at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

The vapor deposition conditions may comprise a deposition temperature. The deposition temperature may be a temperature less than the thermal decomposition temperature of at least one of the vaporized precursor, the at least one vaporized co-reactant precursor, or any combination thereof. The deposition temperature may be sufficiently high to reduce or avoid condensation of at least one of the vaporized precursor, the at least one vaporized co-reactant precursor, or any combination thereof. In some embodiments, the substrate may be heated to the deposition temperature. In some embodiments, the chamber or other vessel in which the substrate is contacted with the vaporized precursor and the at least one vaporized co-reactant precursor is heated to the deposition temperature. In some embodiments, at least one of the vaporized precursor, the at least one vaporized co-reactant precursor, or any combination thereof may be heated to the deposition temperature.

The deposition temperature may be a temperature of 200° C. to 2500° C., or any range or subrange between 200° C. and 2500° C. In some embodiments, the deposition temperature may be a temperature of 500° C. to 700° C. For example, in some embodiments, the deposition temperature may be a temperature of 500° C. to 680° C., 500° C. to 660° C., 500° C. to 640° C., 500° C. to 620° C., 500° C. to 600° C., 500° C. to 580° C., 500° C. to 560° C., 500° C. to 540° C., 500° C. to 520° C., 520° C. to 700° C., 540° C. to 700° C., 560° C. to 700° C., 580° C. to 700° C., 600° C. to 700° C., 620° C. to 700° C., 640° C. to 700° C., 660° C. to 700° C., or 680° C. to 700° C. In other embodiments, the deposition temperature may be a temperature of greater than 200° C. to 2500° C., such as, for example and without limitation, a temperature of 400° C. to 2000, 500° C. to 2000° C., 550° C. to 2400° C., 600° C. to 2400° C., 625° C. to 2400° C., 650° C. to 2400° C., 675° C. to 2400° C., 700° C. to 2400° C., 725° C. to 2400° C., 750° C. to 2400° C., 775° C. to 2400° C., 800° C. to 2400° C., 825° C. to 2400° C., 850° C. to 2400° C., 875° C. to 2400° C., 900° C. to 2400° C., 925° C. to 2400° C., 950° C. to 2400° C., 975° C. to 2400° C., 1000° C. to 2400° C., 1025° C. to 2400° C., 1050° C. to 2400° C., 1075° C. to 2400° C., 1100° C. to 2400° C., 1200° C. to 2400° C., 1300° C. to 2400° C., 1400° C. to 2400° C., 1500° C. to 2400° C., 1600° C. to 2400° C., 1700° C. to 2400° C., 1800° C. to 2400° C., 1900° C. to 2400° C., 2000° C. to 2400° C., 2100° C. to 2400° C., 2200° C. to 2400° C., 2300° C. to 2400° C., 500° C. to 2000° C., 500° C. to 1900° C., 500° C. to 1800° C., 500° C. to 1700° C., 500° C. to 1600° C., 500° C. to 1500° C., 500° C. to 1400° C., 500° C. to 1300° C., 500° C. to 1200° C., 500° C. to 1100° C., 500° C. to 1000° C., 500° C. to 1000° C., 500° C. to 900° C., or 500° C. to 800° C.

The vapor deposition conditions may comprise a deposition pressure. In some embodiments, the deposition pressure may comprise a vapor pressure of at least one of the vaporized precursor, the at least one vaporized co-reactant precursor, or any combination thereof. In some embodiments, the deposition pressure may comprise a chamber pressure.

The deposition pressure may be a pressure of 0.001 Torr to 100 Torr, or any range or subrange between 0.001 Torr and 100 Torr. For example, in some embodiments, the deposition pressure may be a pressure of 1 Torr to 30 Torr, 1 Torr to 25 Torr, 1 Torr to 20 Torr, 1 Torr to 15 Torr, 1 Torr to 10 Torr, 5 Torr to 50 Torr, 5 Torr to 40 Torr, 5 Torr to 30 Torr, 5 Torr to 20 Torr, or 5 Torr to 15 Torr. In other embodiments, the deposition pressure may be a pressure of 1 Torr to 100 Torr, 5 Torr to 100 Torr, 10 Torr to 100 Torr, 15 Torr to 100 Torr, 20 Torr to 100 Torr, 25 Torr to 100 Torr, 30 Torr to 100 Torr, 35 Torr to 100 Torr, 40 Torr to 100 Torr, 45 Torr to 100 Torr, 50 Torr to 100 Torr, 55 Torr to 100 Torr, 60 Torr to 100 Torr, 65 Torr to 100 Torr, 70 Torr to 100 Torr, 75 Torr to 100 Torr, 80 Torr to 100 Torr, 85 Torr to 100 Torr, 90 Torr to 100 Torr, 95 Torr to 100 Torr, 1 Torr to 95 Torr, 1 Torr to 90 Torr, 1 Torr to 85 Torr, 1 Torr to 80 Torr, 1 Torr to 75 Torr, or 1 Torr to 70 Torr. In other further embodiments, the deposition pressure may be a pressure of 1 mTorr to 100 mTorr, 1 mTorr to 90 mTorr, 1 mTorr to 80 mTorr, 1 mTorr to 70 mTorr, 1 mTorr to 60 mTorr, 1 mTorr to 50 mTorr, 1 mTorr to 40 mTorr, 1 mTorr to 30 mTorr, 1 mTorr to 20 mTorr, 1 mTorr to 10 mTorr, 100 mTorr to 300 mTorr, 150 mTorr to 300 mTorr, 200 m Torr to 300 mTorr, or 150 m Torr to 250 mTorr, or 150 mTorr to 225 mTorr.

The substrate may comprise at least one of Si, Co, Cu, AI, W, WN, WC, TIN, Mo, MoC, SiO₂, W, SiN, WCN, Al₂O₃, AlN, ZrO₂, La₂O₃, TaN, RuO₂, IrO₂, Nb₂O₃, Y₂O₃, hafnium oxide, or any combination thereof.

In some embodiments, the silicon-containing film comprises at least one of at least one of silicon, silicon nitride, silicon oxynitride, silicon oxide, silicon dioxide, silicon carbide, silicon carbonitride, silicon oxycarbonitride, carbon-doped silicon nitride, carbon-doped silicon oxide, carbon-doped silicon oxynitride, or any combination thereof. In some embodiments, the substrate may comprise other silicon-based substrates, such as, for example, one or more of polysilicon substrates, metallic substrates, and dielectric substrates.

Some embodiments relate to a film on a substrate. In some embodiments, the film comprises any film formed according to the methods disclosed herein. In some embodiments, the film comprises any film prepared from any one or more of the precursors disclosed herein.

### Example 1

A compound was prepared and compared to two control compounds. The control compounds were prepared according to conventional methods.

A sublimination system was used to prepare the compound. In a glovebox, under a nitrogen atmosphere, crude WCl₅ was added to source containers of the sublimation system. The source containers were then removed from the glovebox. The sublimation system was then pumped down in vacuo to a baseline of 10⁻² Torr and then leak-checked. A line to a carrier gas (argon or nitrogen) was slowly opened to the sublimation system to achieve an internal pressure of 1 to 1.2 Torr. The sublimation system was ramped to a target temperature. The crude WCl₅ was heated to a temperature of 125° C. for 17 hours at a reduced pressure of ˜1 Torr (i.e., dynamic hard vacuum with the argon or nitrogen carrier gas bled into the system to achieve an internal pressure of 1-1.2 Torr). The heating step conditioned and removed volatile impurities from the crude WCl₅ prior to conducting sublimation. Powder X-ray diffraction (PXRD) was used to determine that the novel orthorhombic crystalline phase comprised 0.9% of the total mixture.

The crystal structure of the compound and the control compounds was determined using Single-Crystal X-ray Diffraction. The crystal structure data is summarized in Table 2 below.

TABLE 2
Crystal Structure Data

| | Control 1 | | Control 2 | | Compound | |
|---|---|---|---|---|---|---|
| Temperature (Kelvin) | 280 | | 293 | | 290 | |
| Color | Dark Green | | Dark Green | | Dark Green | |
| Crystal System | Monoclinic | | Monoclinic | | Orthorhombic | |
| Space Group | C2/m | | C2/m | | Pnma | |
| a (Å) | 18.090 | (3) | 17.458 | (3) | 11.5854 | (5) |
| b (Å) | 17.714 | (2) | 17.752 | (3) | 17.7108 | (8) |
| c (Å) | 5.8013 | (8) | 6.0633 | (9) | 6.0637 | (3) |
| α (°) | 90 | | 90 | | 90 | |
| β (°) | 90.314 | (5) | 95.554 | (5) | 90 | |
| γ (°) | 90 | | 90 | | 90 | |
| V (Å³) | 1859.0 | (4) | 1870.3 | (5) | 1244.19 | (10) |

| | | | |
|---|---|---|---|
| Z | 6 | 6 | 4 |
| Density (g/cm³) | 3.871 | 3.847 | 3.855 |
| R₁ (%) | 1.51 | 2.03 | 2.23 |
| wR2 (%) | 3.12 | 4.85 | 4.54 |
| GooF | 1.189 | 1.128 | 1.038 |

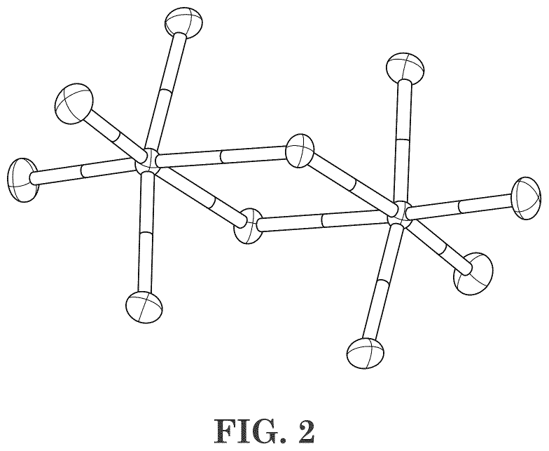

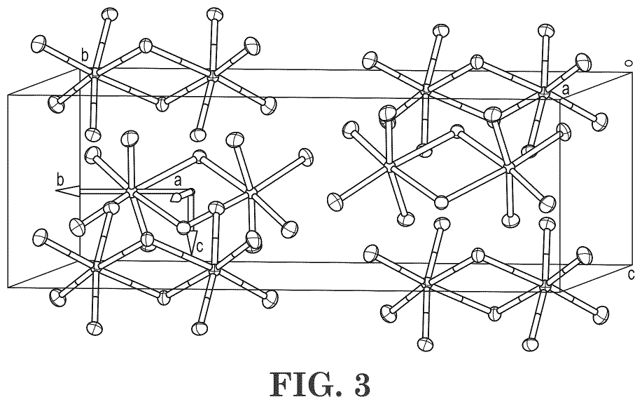

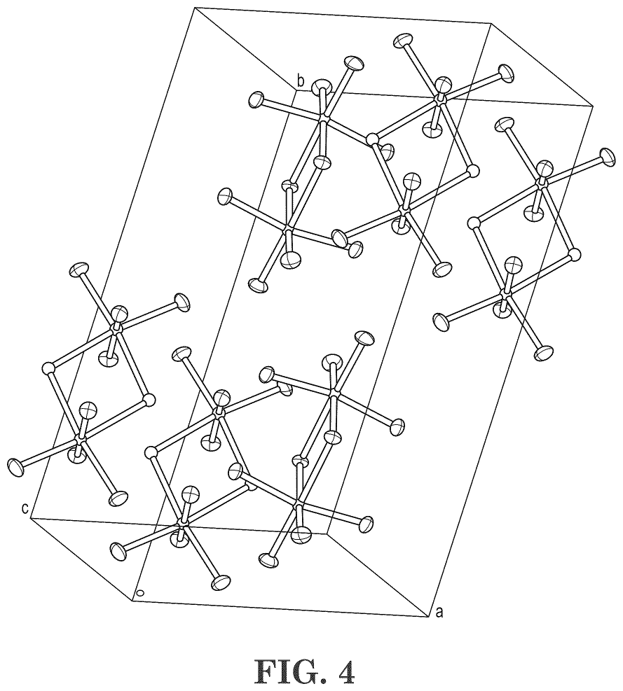

As shown above in Table 2, the compound was determined to have an orthorhombic crystal structure as determined by Single-Crystal X-ray Diffraction. In contrast, the control compounds 1 and 2 both were determined to have monoclinic crystal structures. FIGS. 2-4 are different views of an orthorhombic crystal structure as determined using Single-Crystal X-ray Diffraction.

### Example 2

A sublimation system was used to prepare the compound. In a glovebox, under a nitrogen atmosphere, crude WCl₅ was added to a source container of the sublimation system. The source container was then removed from the glovebox. The sublimation system was then pumped down in vacuo to a baseline of 10⁻² Torr and then leak-checked. The crude WCl₅ was heated to a temperature of 175° C. and maintained at this temperature for 96 hours under static reduced pressure. Subsequently, the system was allowed to cool to 110° C. The system was opened to dynamic vacuum and a line to a carrier gas (argon or nitrogen) was slowly opened to the sublimation system to achieve an internal pressure of 1 to 1.2 Torr. The sublimation system was ramped to a target temperature. The WCl₅ was heated to a temperature of 175° C. at a reduced pressure of ˜1 Torr (i.e., dynamic hard vacuum with the argon or nitrogen carrier gas bled into the system to achieve an internal pressure of 1-1.2 Torr). The heating step conditioned and removed volatile impurities from the crude WCl₅ prior to conducting sublimation. Powder X-ray diffraction (PXRD) was used to determine that the novel orthorhombic crystalline phase comprised 27.6% of the total mixture.

### Aspects

Various Aspects are described below. It is to be understood that any one or more of the features recited in the following Aspect(s) can be combined with any one or more other Aspect(s).
Aspect 1. A composition comprising:
   a tungsten pentachloride compound,
      wherein the tungsten pentachloride compound has an orthorhombic crystal structure as determined using Single-Crystal X-ray Diffraction.
Aspect 2. The composition according to Aspect 1, having unit cell dimensions of:

$$a = 11.5854 ( 5 ) A \qquad α = 90 °$$

$$\begin{matrix}b = 17.7108 ( 8 ) A & β\end{matrix} = 90 °$$

$$\begin{matrix}c = 6.0637 ( 3 ) A & γ\end{matrix} = 90 °$$

$$cell volume ( {A}^{3} ) = 1244.19 ( 10 ) {A}^{3} .$$

Aspect 3. The composition according to any one of Aspects 1-2, wherein the tungsten pentachloride compound has a purity of at least 99%.
Aspect 4. The composition according to any one of Aspects 1-3, wherein the tungsten pentachloride compound has a purity of 99% to 99.9999%.
Aspect 5. The composition according to any one of Aspects 1-4, wherein the tungsten pentachloride compound has a space group of Pnma as determined using Single-Crystal X-ray Diffraction.
Aspect 6. The composition according to any one of Aspects 1-5, wherein the tungsten pentachloride compound has a point group of mmm as determined using Single-Crystal X-ray Diffraction.
Aspect 7. A precursor comprising:
   a tungsten pentachloride compound,
      wherein the tungsten pentachloride compound has an orthorhombic crystal structure.
Aspect 8. The precursor according to Aspect 7, wherein the tungsten pentachloride compound has purity of at least 99%.
Aspect 9. The precursor according to any one of Aspects 7-8, wherein the tungsten pentachloride compound has purity of 99% to 99.9999.
Aspect 10. The precursor according to any one of Aspects 7-9, having a unit cell dimension of:

$$a = 11.5854 ( 5 ) A \qquad α = 90$$

$$\begin{matrix}b = 17.7108 ( 8 ) A & β\end{matrix} = 90$$

$$\begin{matrix}c = 6.0637 ( 3 ) A & γ\end{matrix} = 90$$

$$cell volume = 1244.19 ( 10 ) {A}^{3} .$$

$$Z = 4.$$

Aspect 11. The precursor according to any one of Aspects 7-10, wherein the tungsten pentachloride compound has a point group of mmm as determined using Single-Crystal X-ray Diffraction.
Aspect 12. The precursor according to any one of Aspects 7-11, wherein the tungsten pentachloride compound has a space group of Pnma as determined using Single-Crystal X-ray Diffraction.
Aspect 13. A method comprising:
   obtaining a precursor,
      wherein the precursor comprises:
         a tungsten pentachloride compound,
         wherein the tungsten pentachloride compound has an orthorhombic crystal structure as determined by Single-Crystal X-Ray Diffraction;
   vaporizing the precursor to obtain a vaporized precursor; and
   exposing, under vapor deposition conditions, a substrate to the vaporized precursor.
Aspect 14. The method according to Aspect 13, further comprising:
   obtaining at least one co-reactant precursor;
   vaporizing the at least one co-reactant precursor to obtain at least one vaporized co-reactant precursor; and
   exposing, under vapor deposition conditions, the substrate to the at least one vaporized co-reactant precursor to form a film on the substrate.
Aspect 15. The method according to Aspect 14, wherein the substrate is sequentially exposed to the at least one vaporized co-reactant precursor and the vaporized precursor.
Aspect 16. The method according to any one of Aspects 13-15, wherein the tungsten pentachloride compound has purity of at least 99%.
Aspect 17. The method according to any one of Aspects 13-16, wherein the tungsten pentachloride compound has a purity of 99% to 99.9999%.
Aspect 18. The method according to any one of Aspects 13-17, having a unit cell dimension of:

$$a = 11.5854 ( 5 ) A \qquad α = 90 °$$

$$\begin{matrix}b = 17.7108 ( 8 ) A & β\end{matrix} = 90 °$$

$$\begin{matrix}c = 6.0637 ( 3 ) A & γ\end{matrix} = 90 °$$

$$cell volume = 1244.19 ( 10 ) {A}^{3}$$

$$Z = 4.$$

Aspect 19. The method according to any one of Aspects 13-18, wherein the tungsten pentachloride compound has a point group of mmm as determined using Single-Crystal X-ray Diffraction.
Aspect 20. The method according to any one of Aspects 13-19, wherein the tungsten pentachloride compound has a space group of Pnma as determined using Single-Crystal X-ray Diffraction.

What is claimed is:

1. A composition comprising:
a tungsten pentachloride compound,
wherein the tungsten pentachloride compound has an orthorhombic crystal structure as determined using Single-Crystal X-ray Diffraction.

2. The composition of claim 1, having a unit cell dimension of:
$$a = 11.5854 ( 5 ) A \qquad α = 90 °$$
$$\begin{matrix}b = 17.7108 ( 8 ) A & β\end{matrix} = 90 °$$
$$\begin{matrix}c = 6.0637 ( 3 ) A & γ\end{matrix} = 90 °$$
$$cell volume = 1244.19 ( 10 ) {A}^{3}$$
$$Z = 4.$$

3. The composition of claim 1, wherein the tungsten pentachloride compound has purity of at least 99%.

4. The composition of claim 1, wherein the tungsten pentachloride compound has a purity of 99% to 99.9999%.

5. The composition of claim 1, wherein the tungsten pentachloride compound has a space group of Pnma as determined using Single-Crystal X-ray Diffraction.

6. The composition of claim 1, wherein the tungsten pentachloride compound has a point group of mmm as determined using Single-Crystal X-ray Diffraction.

7. A precursor comprising:
a tungsten pentachloride compound,
wherein the tungsten pentachloride compound has an orthorhombic crystal structure.

8. The precursor of claim 7, wherein the tungsten pentachloride compound has purity of at least 99%.

9. The precursor of claim 7, wherein the tungsten pentachloride compound has a purity of 99% to 99.9999%.

10. The precursor of claim 7, having a unit cell dimension of:
$$a = 11.5854 ( 5 ) A \qquad α = 90 °$$
$$\begin{matrix}b = 17.7108 ( 8 ) A & β\end{matrix} = 90 °$$
$$\begin{matrix}c = 6.0637 ( 3 ) A & γ\end{matrix} = 90 °$$
$$cell volume = 1244.19 ( 10 ) {A}^{3}$$
$$Z = 4.$$

11. The precursor of claim 7, wherein the tungsten pentachloride compound has a point group of mmm as determined using Single-Crystal X-ray Diffraction.

12. The precursor of claim 7, wherein the tungsten pentachloride compound has a space group of Pnma as determined using Single-Crystal X-ray Diffraction.

13. A method comprising:
obtaining a precursor,
wherein the precursor comprises:
a tungsten pentachloride compound,
wherein the tungsten pentachloride compound has an orthorhombic crystal structure as determined by Single-Crystal X-Ray Diffraction;
vaporizing the precursor to obtain a vaporized precursor; and
exposing, under vapor deposition conditions, a substrate to the vaporized precursor.

14. The method of claim 13, further comprising:
obtaining at least one co-reactant precursor;
vaporizing the at least one co-reactant precursor to obtain at least one vaporized co-reactant precursor; and
exposing, under vapor deposition conditions, the substrate to the at least one vaporized co-reactant precursor to form a film on the substrate.

15. The method of claim 14, wherein the substrate is sequentially exposed to the at least one vaporized co-reactant precursor and the vaporized precursor.

16. The method of claim 13, wherein the tungsten pentachloride compound has purity of at least 99%.

17. The method of claim 13, wherein the tungsten pentachloride compound has a purity of 99% to 99.9999%.

18. The method of claim 13, having a unit cell dimension of:
$$a = 11.5854 ( 5 ) A \qquad α = 90 °$$
$$\begin{matrix}b = 17.7108 ( 8 ) A & β\end{matrix} = 90 °$$
$$\begin{matrix}c = 6.0637 ( 3 ) A & γ\end{matrix} = 90 °$$
$$cell volume = 1244.19 ( 10 ) {A}^{3}$$
$$Z = 4.$$

19. The method of claim 13, wherein the tungsten pentachloride compound has a point group of mmm as determined using Single-Crystal X-ray Diffraction.

20. The method of claim 13, wherein the tungsten pentachloride compound has a space group of Pnma as determined using Single-Crystal X-ray Diffraction.
